(19) United States
(12) Patent Application Publication
(10) Pub. No.: US 2017/0084490 A1
(43) Pub. Date: Mar. 23, 2017

(54) METHOD FOR MAKING IC WITH STEPPED SIDEWALL AND RELATED IC DEVICES

(71) Applicant: STMICROELECTRONICS, INC., Calamba City (PH)

(72) Inventors: Bryan Christian Bacquian, Calamba (PH); Frederick Arellano, Pulo Cabuyao Laguna (PH); Aiza Marie Agudon, Calamba City (PH)

(21) Appl. No.: 14/857,965

(22) Filed: Sep. 18, 2015

(51) Int. Cl. H01L 21/78; H01L 21/66; H01L 23/31; H01L 23/00; H01L 21/56; H01L 21/683; H01L 23/29

(52) U.S. Cl. CPC H01L 21/78; H01L 21/6836; H01L 22/12; H01L 23/293; H01L 24/49; H01L 21/56; H01L 23/3142; H01L 2221/68327; H01L 2924/14; H01L 2224/48225; H01L 2221/6834

(57) ABSTRACT

A method is for making an integrated circuit (IC) device. The method may include dicing a wafer into IC dies, each IC die having an active surface, a back surface opposite the active surface, and a sidewall with a step defining a smaller periphery adjacent the back surface and a larger periphery adjacent the active surface. The method may include positioning a resin material between the back surface of each IC die and a respective substrate, and around each IC die so that the resin material abuts and is retained by the step.

### TECHNICAL FIELD

The present disclosure relates to the field of electronic devices, and, more particularly, to semiconductor devices and related methods.

### BACKGROUND

In electronic devices with integrated circuits (ICs), the ICs are typically mounted onto circuit boards. In order to electrically couple connections between the circuit board and the IC, the IC is typically “packaged.” The IC packaging usually provides a small encasement for physically protecting the IC and provides contact pads for coupling to the circuit board. In some applications, the packaged IC may be coupled to the circuit board via solder bumps.

One approach to IC packaging comprises mounting an IC onto a circuit board, and coupling the IC to the circuit board via a plurality of bond wires. Bond wire methods are generally considered the most cost-effective and flexible interconnect technology, and are used to assemble the vast majority of semiconductor packages.

Referring initially to FIG. 1, a typical method for making an IC device 100 is now described. The method includes positioning a wafer 109 on a carrier layer 104. The wafer 109 includes a plurality of IC dies 105a-105c, each IC die having an active surface 107 and a back surface 108. The active surface 107 includes circuitry 111. The method includes dicing the wafer 109 with first and second dicing blades 101-102 to singulate the plurality of IC dies 105a-105c from the active surface 107. Once singulated, each IC die 105a-105c is mounted onto a respective circuit board layer 103, and encapsulation material 106 is formed between the IC die and the respective circuit board layer. The method also includes forming a plurality of bond wires 110a-11b between the IC die 105a-105c and the respective circuit board layer 103.

### SUMMARY

Generally speaking, a method is for making an IC device. The method may include dicing a wafer into a plurality of IC dies. Each IC die may have an active surface, a back surface opposite the active surface, and a sidewall with a step therein defining a smaller periphery adjacent the back surface and a larger periphery adjacent the active surface. The method may include positioning a resin material between the back surface of each IC die and a respective substrate, and around each IC die so that the resin material abuts and is retained by the step. Advantageously, the method may provide an improved yield rate for production of the IC devices.

In particular, positioning the resin material may comprise positioning the resin material to not extend past the step. The method may further comprise positioning the wafer on an adhesive carrier layer before dicing, and removing the plurality of IC dies from the adhesive carrier layer after dicing.

Also, positioning the wafer on the adhesive carrier layer may comprise positioning the active surface onto the adhesive carrier layer. The method may also comprise aligning at least one dicing blade using an image sensor device adjacent the back surface of the IC dies. The wafer may comprise scribe lines between adjacent ones of the plurality of IC dies, and the image sensor device may sense the scribe lines. In some embodiments, the image sensor device may comprise an infrared image sensor device.

Moreover, dicing the wafer may comprise a first partial dicing with a first dicing blade, and a second partial dicing with a second dicing blade. The first dicing blade may have a thickness different than that of the second dicing blade.

Another aspect is directed to an IC device. The IC device may include a substrate, and an IC die adjacent the substrate. The IC die may have an active surface, a back surface opposite the active surface, and a sidewall with a step therein defining a smaller periphery adjacent the back surface and a larger periphery adjacent the active surface. The IC device may include resin material between the back surface of the IC die and the substrate, and around the IC die, the resin material abutting the step, being retained by the step, and not extending past the step.

Additionally, the IC device may further comprise a plurality of bond wires extending between the substrate and the IC die. The active surface may comprise circuitry. The larger periphery may have a width in a range of 105%-125% of a width of the smaller periphery.

### BRIEF DESCRIPTION OF THE DRAWINGS

FIG. 1 is a schematic side view of a step for a method for making an IC device, according to the prior art.

FIG. 2 is a schematic side view of an IC device, according to the prior art.

FIG. 3 is a schematic side view of a step for a method for making an IC device, according to the present disclosure.

FIG. 4 is a schematic side view of an IC device, according to the present disclosure.

FIG. 5 is a flowchart of a method for making the IC device, according to the present disclosure.

FIG. 6 is a more detailed flowchart of the method for making the IC device, according to the present disclosure.

### DETAILED DESCRIPTION

The present disclosure will now be described more fully hereinafter with reference to the accompanying drawings, in which several embodiments of the invention are shown. This present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout.

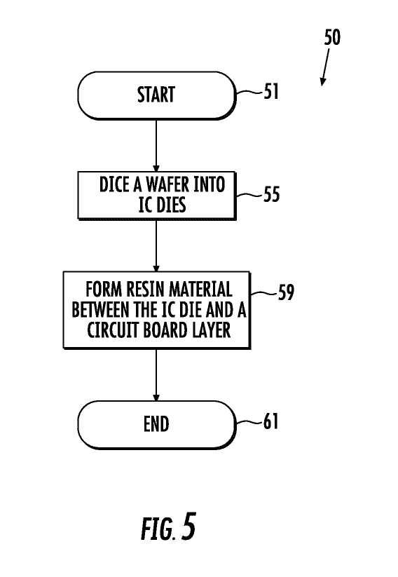

Referring now to FIGS. 3-4, an IC device 10 and a method for making the IC device according to the present disclosure are now described. The IC device 10 illustratively includes a substrate (e.g. a circuit board layer or a lead frame component) 12, and an IC die 11 mounted onto the substrate. In some embodiments, the substrate comprises a circuit board layer 12 including a dielectric layer, and a plurality of electrically conductive traces carried by the dielectric layer. The IC die 11 illustratively includes an active surface 14, a back surface 15 opposite the active surface, and sidewalls 16-17. The active surface 14 illustratively includes circuitry 26, and a plurality of bond pads 27a-27b. For example, the circuitry 26 may comprise image sensing circuitry.

Each sidewall 16-17 has a step 18-19 defining a smaller periphery adjacent the back surface 15 and a larger periphery adjacent the active surface 14. Although only two sidewalls 16-17 are depicted, the IC die 11 has four such sidewalls 16-17 with steps 18-19.

In other words, the width and length across the back surface 15 are less than the width and length across the active surface 14. In particular, the larger periphery may have a width and length respectively in a range of 105%-125% of a width and a length of the smaller periphery.

The IC device 10 illustratively includes resin material (e.g. epoxy material) 13 between the back surface 15 of the IC die 11 and the substrate 12, and around the IC die, the resin material abutting the steps 18-19, being retained by the steps, and not extending past the steps. Advantageously, the fillet height (i.e. the height of the resin material 13 measured from the substrate 12 to the steps 18-19) is tightly controlled, thereby preventing the resin material from contaminating/encroaching the active surface 14 and the plurality of bond pads 27a-27b. Additionally, the IC device 10 illustratively includes a plurality of bond wires 25a-25b extending between the plurality of electrically conductive traces of the substrate 12 and the plurality of bond pads 27a-27b of the IC die 11. Helpfully, since the fillet height is controlled, the formation of the bond wires 25a-25b is not affected by the resin material 13.

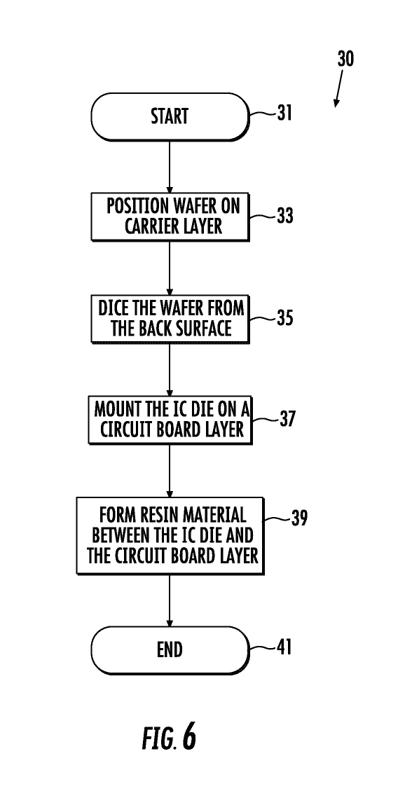

Referring now additionally to FIGS. 5-6 and flowcharts 30, 50 in these figures, the method for making the IC device 10 begins at Blocks 31 and 51. The method illustratively includes positioning a wafer 23 on an adhesive carrier layer 22. (Block 33). The wafer 23 illustratively includes a plurality of IC dies 11a-11c. Each IC die 11a-11c has have an active surface 14a-14c, and a back surface 15a-15c opposite the active surface. In particular, the wafer 23 is positioned so that the active surfaces 14a-14c of the plurality of IC dies 11a-11c are faced downward onto the adhesive carrier layer 22. In particular, the adhesive carrier layer 22 may comprise a front side protection (FSP) tape.

The method illustratively includes dicing the wafer 23 into a plurality of IC dies 11a-11c (i.e. a singulation step). (Blocks 35, 55). The method illustratively includes aligning first and second dicing blades 20-21 using an image sensor device 24 adjacent the back surfaces 15a-15c of the IC dies 11a-11c, i.e. the dicing is performed on the back surfaces of the IC dies. As will be appreciated, the wafer 23 comprises scribe lines 28 (shown with dashed line) between adjacent ones of the plurality of ICs dies 11a-11c, and the image sensor device 24 may sense the scribe lines. In some embodiments, the image sensor device 24 may comprise an infrared image sensor device. In some embodiments, the image sensor device 24 may sense buried metallization layers in the wafer 23.

Moreover, the dicing of the wafer 23 comprises a first partial dicing with the first dicing blade 20, and a second partial dicing with a second dicing blade 21. The first dicing blade 20 may have a thickness different than that of the second dicing blade 21. Each IC die 11a-11c has sidewalls 16-17, and as perhaps best seen in FIG. 3, the multi-blade dicing defines each sidewall 16-17 to have a step 18-19 defining a smaller periphery adjacent the back surface 15a-15c and a larger periphery adjacent the active surface 14a-14c. In the illustrated embodiment, the first dicing blade 20 is thicker than the second dicing blade 21, and the second dicing blade dices to a greater depth into the wafer 23 than the first dicing blade. Advantageously, the active surfaces 14a-14c are shielded from debris during dicing.

The method illustratively includes removing the plurality of IC dies ha-11c from the adhesive carrier layer 22 after dicing, and mounting the plurality of IC dies on respective substrates 12. (Block 37). The method illustratively includes positioning/forming a resin material 13 between the back surface 15a-15c of each IC die 11a-11c and a respective substrate 12, and around each IC die so that the resin material abuts and is retained by the step 18-19. (Blocks 39, 59 & 41, 61). In particular, positioning the resin material 13 may comprise positioning the resin material to not extend past the step 18-19.

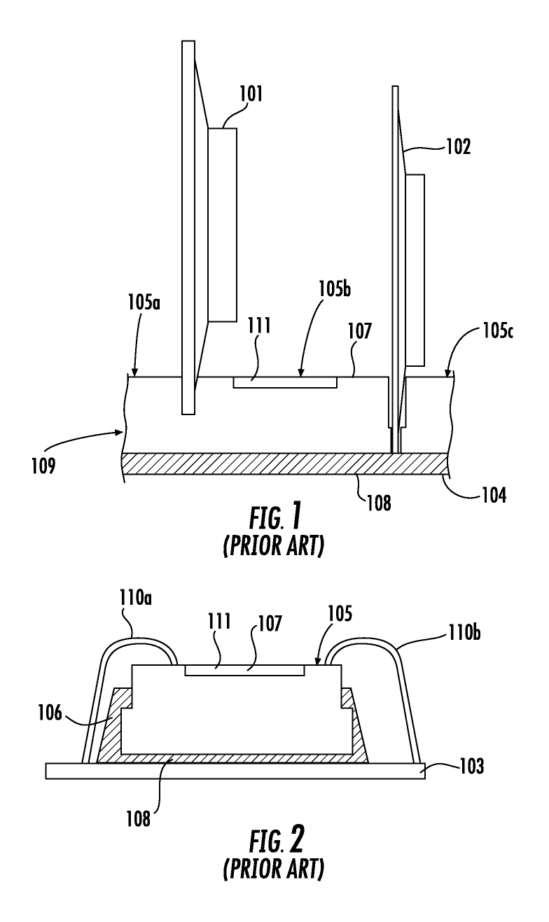

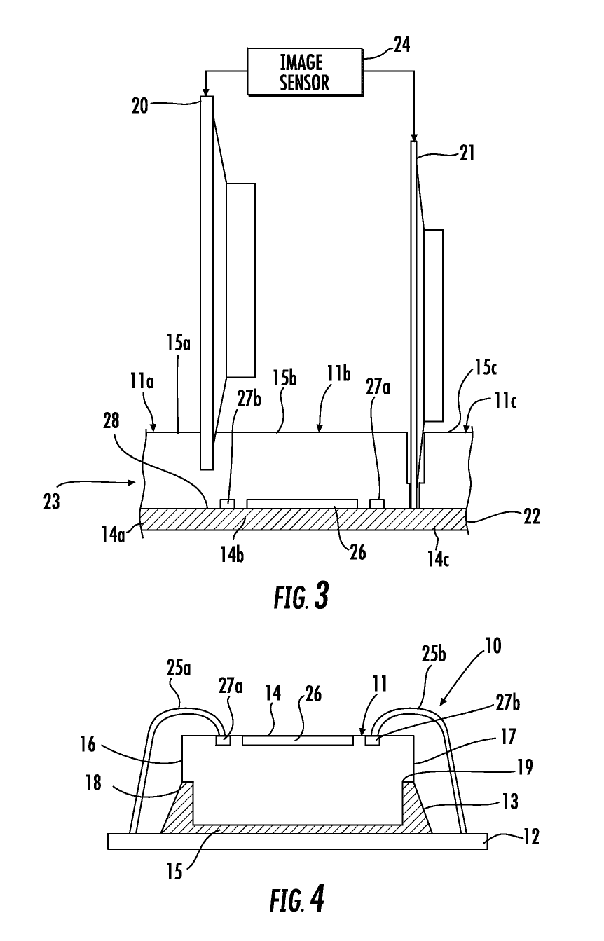

In typical approaches, such as shown in FIGS. 1-2, the manufacturing process would have reduced yield due to the lack of control of the fillet height. In particular, the encapsulation material 106 would encroach on the active surface 107 of the IC die 105a-105c and encroach upon the plurality of bond wires 110a-110b. Indeed, as IC dies become thinner (i.e. about 100 μm in IC die height), the issue of fillet height control has become more pronounced. Also, the approach in FIGS. 1-2 may contaminate the active surface 107 with debris from the dicing process. Advantageously, the method may provide an improved yield rate for production of the IC devices 10 due to less encroachment of the bond wires 25a-25b and the active surface 14, and less contamination of the active surface due from the dicing process.

Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. A method for making an integrated circuit (IC) device, the method comprising:
dicing a wafer into a plurality of IC dies, each IC die having
an active surface,
a back surface opposite the active surface, and
a sidewall with a step therein defining a smaller periphery adjacent the back surface and a larger periphery adjacent the active surface;
positioning a resin material between the back surface of each IC die and a respective substrate, and around each IC die so that the resin material abuts and is retained by the step; and
forming a plurality of bond wires extending between the respective substrate and the active surface of each IC die.

2. The method of claim 1 wherein positioning the resin material comprises positioning the resin material to not extend past the step.

3. The method of claim 1 further comprising:
positioning the wafer on an adhesive carrier layer before dicing; and
removing the plurality of IC dies from the adhesive carrier layer after dicing.

4. The method of claim 3 wherein positioning the wafer on the adhesive carrier layer comprises positioning the active surface onto the adhesive carrier layer.

5. The method of claim 3 further comprising aligning at least one dicing blade using an image sensor device adjacent the back surface of the IC dies.

6. The method of claim 5 wherein the wafer comprises scribe lines between adjacent ones of the plurality of IC dies; and wherein the image sensor device senses the scribe lines.

7. The method of claim 5 wherein the image sensor device comprises an infrared image sensor device.

8. The method of claim 1 wherein dicing the wafer comprises a first partial dicing with a first dicing blade, and a second partial dicing with a second dicing blade.

9. The method of claim 8 wherein the first dicing blade has a thickness different than that of the second dicing blade.

10. A method for making an integrated circuit (IC) device, the method comprising:
positioning a wafer on an adhesive carrier layer before dicing;
dicing the wafer into a plurality of IC dies, each IC die having
an active surface,
a back surface opposite the active surface, and
a sidewall with a step therein defining a smaller periphery adjacent the back surface and a larger periphery adjacent the active surface;
removing the plurality of IC dies from the adhesive carrier layer after dicing;
positioning a resin material between the back surface of each IC die and a respective substrate, and around each IC die so that the resin material abuts the step, is retained by the step, and does not extend past the step; and
forming a plurality of bond wires extending between the respective substrate and the active surface of each IC die.

11. The method of claim 10 wherein positioning the wafer on the adhesive carrier layer comprises positioning the active surface onto the adhesive carrier layer.

12. The method of claim 10 further comprising aligning at least one dicing blade using an image sensor device adjacent the back surface of the IC dies.

13. The method of claim 12 wherein the wafer comprises scribe lines between adjacent ones of the plurality of IC dies; and wherein the image sensor device senses the scribe lines.

14. The method of claim 12 wherein the image sensor device comprises an infrared image sensor device.

15. The method of claim 10 wherein dicing the wafer comprises a first partial dicing with a first dicing blade, and a second partial dicing with a second dicing blade.

16. The method of claim 15 wherein the first dicing blade has a thickness different than that of the second dicing blade.

17-20. (canceled)

21. A method for making an integrated circuit (IC) device, the method comprising:
dicing a wafer into a plurality of IC dies, each IC die having
an active surface,
a back surface opposite the active surface, and
a sidewall with a step therein defining a smaller periphery adjacent the back surface and a larger periphery adjacent the active surface;
the dicing of the wafer comprising a first partial dicing with a first dicing blade to a first depth from the back surface, and a second partial dicing with a second dicing blade to a second depth from the back surface, the second depth being greater than the first depth, the second dicing blade having a second width less than a first width of the first dicing blade; and
positioning a resin material between the back surface of each IC die and a respective substrate, and around each IC die so that the resin material abuts and is retained by the step.

22. The method of claim 21 wherein positioning the resin material comprises positioning the resin material to not extend past the step.

23. The method of claim 21 further comprising:
positioning the wafer on an adhesive carrier layer before dicing; and
removing the plurality of IC dies from the adhesive carrier layer after dicing.

24. The method of claim 23 wherein positioning the wafer on the adhesive carrier layer comprises positioning the active surface onto the adhesive carrier layer.
